(19) United States
(12) Patent Application Publication
(10) Pub. No.: US 2022/0068657 A1
(43) Pub. Date: Mar. 3, 2022

(54) ETCHING METHOD AND ETCHING APPARATUS

(71) Applicant: Tokyo Electron Limited, Minato-ku, Tokyo (JP)

(72) Inventors: Koji TAKEYA, Nirasaki City (JP); Gen YOU, Nirasaki City (JP); Jeongchan LEE, Nirasaki City (JP); Satoshi TODA, Nirasaki City (JP); Keiko HADA, Nirasaki City (JP)

(21) Appl. No.: 17/445,961

(22) Filed: Aug. 26, 2021

(30) Foreign Application Priority Data
Aug. 28, 2020 (JP) 2020-144867
Jun. 18, 2021 (JP) 2021-101853

(51) Int. Cl. H01L 21/311; H01L 21/67

(52) U.S. Cl. CPC H01L 21/31116; H01L 21/67069

(57) ABSTRACT

An etching method of an oxygen-containing silicon film embedded in each recess of a substrate, which includes a plurality of recesses having different opening sizes, by supplying an etching gas to the substrate, the etching method including: adsorbing an organic amine compound gas on the oxygen-containing silicon film by supplying the organic amine compound gas to the substrate; desorbing an excess of the organic amine compound gas from the substrate; and selectively etching the oxygen-containing silicon film with respect to each recess by supplying the etching gas containing a halogen to the substrate on which the organic amine compound has been adsorbed.

### CROSS-REFERENCE TO RELATED APPLICATIONS

This application is based upon and claims the benefit of priority from Japanese Patent Application Nos. 2020-144867 and 2021-101853, filed on Aug. 28, 2020 and Jun. 18, 2021, respectively, the entire contents of which are incorporated herein by reference.

### TECHNICAL FIELD

The present disclosure relates to an etching method and an etching apparatus.

### BACKGROUND

In manufacturing a semiconductor device, etching is performed on an oxygen-containing silicon film such as a silicon oxide (SiOₓ) film formed on a semiconductor wafer (hereinafter, referred to as a “wafer”), which is a substrate. For example, Patent Document 1 describes etching a SiOₓ film by supplying hydrogen fluoride (HF) gas and organic amine compound gas.

### PRIOR ART DOCUMENT cl Patent Document

Japanese Patent No. 6700571

### SUMMARY

An etching method of the present disclosure is etching an oxygen-containing silicon film embedded in each recess of a substrate, which includes a plurality of recesses having different opening sizes, by supplying an etching gas to the substrate. The etching method includes: adsorbing an organic amine compound gas on the oxygen-containing silicon film by supplying the organic amine compound to the substrate; desorbing an excess of the organic amine compound gas to be desorbed from the substrate; and selectively etching the oxygen-containing silicon film with respect to each recess by supplying the etching gas containing a halogen to the substrate on which the organic amine compound has been adsorbed.

Another etching method of the present disclosure is etching an oxygen-containing silicon film by supplying an etching gas to a substrate. The etching method includes: adsorbing an organic amine compound gas on the oxygen-containing silicon film by supplying the organic amine compound gas to the substrate; desorbing an excess of the organic amine compound gas to be desorbed from the substrate by supplying an inert gas to the substrate; and etching the oxygen-containing silicon film by supplying the etching gas containing a halogen to the substrate on which the organic amine compound has been adsorbed.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a side view of an etching apparatus according to an embodiment for performing an etching method of the present disclosure.

FIG. 2 is a vertical cross-sectional view illustrating an exemplary wafer processed by the etching apparatus.

FIG. 3 is a flowchart illustrating a first etching method.

FIG. 4 is a timing chart illustrating timing of the supply/the stop of supply of gas in the first etching method.

FIG. 5A is a vertical cross-sectional view of a wafer during processing.

FIG. 5B is a vertical cross-sectional view of the wafer during processing.

FIG. 6A is a vertical cross-sectional view of the wafer during processing.

FIG. 6B is a vertical cross-sectional view of the wafer during processing.

FIG. 7A is a vertical cross-sectional view of the wafer during processing.

FIG. 7B is a vertical cross-sectional view of the wafer during processing.

FIG. 8A is a vertical cross-sectional view of the wafer during processing.

FIG. 8B is a vertical cross-sectional view of the wafer during processing.

FIG. 9A is a vertical cross-sectional view of the wafer during processing.

FIG. 9B is a vertical cross-sectional view of the wafer during processing.

FIG. 10 is a vertical cross-sectional view of the wafer.

FIG. 11 is a timing chart illustrating timing of the supply/the stop of supply of gas in a second etching method.

FIG. 12A is a vertical cross-sectional view of the wafer during processing.

FIG. 12B is a vertical cross-sectional view of the wafer during processing.

FIG. 13A is a vertical cross-sectional view of the wafer during processing.

FIG. 13B is a vertical cross-sectional view of the wafer during processing.

FIG. 14A is an explanatory view illustrating a state inside a recess in a wafer.

FIG. 14B is the explanatory view illustrating the state inside the recess in a wafer.

FIG. 15 is a vertical cross-sectional view of a wafer which is being processed by a third etching method.

FIG. 16 is a graph showing the results of an evaluation test.

FIG. 17 is a graph showing the results of the evaluation test.

FIG. 18 is a graph showing the results of the evaluation test.

FIG. 19 is a schematic view illustrating vertical cross sections of a wafer W imaged in an evaluation test.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

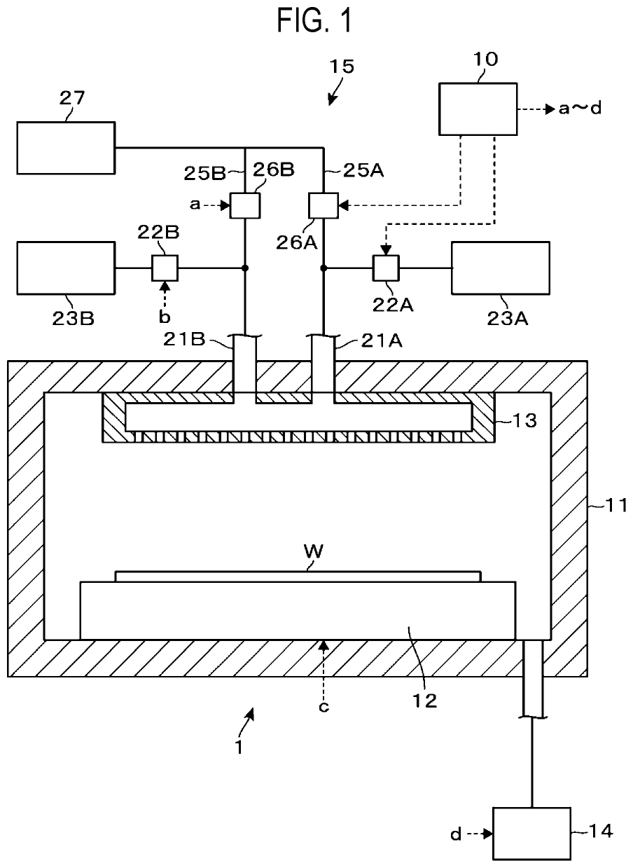

FIG. 1 illustrates an etching apparatus 1 according to an embodiment of the etching apparatus of the present disclosure. The etching apparatus 1 is configured to be capable of performing first to third etching methods to be described later. The outline of the first to third etching methods will be described first. With respect to a SiOₓ film, which is an oxygen-containing Si (silicon) film formed on the surface of a wafer W, etching is performed using hydrogen fluoride (HF) gas, which is an etching gas, and trimethylamine (TMA) gas, which is an organic amine compound gas.

More specifically, as will be shown later in the evaluation tests, TMA gas has a high adsorption property with respect to an SiOₓ film and reacts with HF gas to enhance the etching property of the HF gas with respect to the SiOₓ film. Using these properties, in the first to third etching methods, a SiOₓ film is selectively etched with respect to a film other than the SiOₓ film formed on the surface of a wafer W. No plasma is used for etching.

The etching apparatus 1 includes a processing container 11, a stage 12, a shower head 13, an exhaust mechanism 14, and a piping system 15. The inside of the processing container 11 is exhausted by the above-mentioned exhaust mechanism 14 including, for example, a vacuum pump, an exhaust pipe, a valve interposed in the exhaust pipe, and the like so as to obtain a vacuum atmosphere having a desired pressure. In addition, the stage 12 provided in the processing container 11 is provided with a heater, and a wafer W placed on the stage 12 is heated to a desired temperature by the heater. The processing container 11 is provided with a wafer W transport port that is openable/closable, and the stage 12 is provided with pins each of which is movable up and down. A wafer W is transported between a transport mechanism of the wafer W that has entered the processing container 11 via the transport port and a position above the stage 12. However, illustration of the transport port and pins is omitted.

The shower head 13, which is an organic amine compound gas supplier and an etching gas supplier, is installed on the ceiling in the processing container 11 so as to face the stage 12, and supplies a gas to the entire surface of the wafer W placed on the stage 12. The piping system 15 is configured to be capable of supplying the above-mentioned HF gas and TMA gas to the wafer W through the shower head 13. Next, the configuration of the piping system 15 will be described. The piping system 15 includes pipes 21A and 21B, the downstream sides of which are each connected to the shower head 13. The upstream side of the pipe 21A is connected to a HF gas supply source 23A via a gas supply device 22A, and the upstream side of the pipe 21B is connected to a TMA gas supply source 23B via a gas supply device 22B.

The downstream side of the pipe 25A is connected to the downstream side of the gas supply device 22A in the pipe 21A, and the upstream side of the pipe 25A is connected to the supply source 27 of an inert gas (e.g., nitrogen (N₂) gas) via a gas supply device 26A. The downstream side of a pipe 25B is connected to the downstream side of the gas supply device 22B in the pipe 21B, and the upstream side of the pipe 25B is connected to the N₂ gas supply source 27 via a gas supply device 26B. The gas supply devices 22A, 22B, 26A, and 26B are provided with respective flow rate control devices, such as valves and mass flow controllers, so that the supply/the stop of supply and the flow rates of respective gases supplied from the gas supply sources to the downstream side can be controlled.

The N₂ gas is used as a carrier gas for TMA gas, a carrier gas for HF gas, and a purge gas for purging the inside of the processing container 11. For example, N₂ gas is constantly supplied to the pipes 21A and 21B during the processing of the wafer W. As a result, when TMA gas or HF gas is supplied into the processing container 11, the N₂ gas is used as a carrier gas for the TMA gas or HF gas, and when neither HF gas nor TMA gas is supplied, the N₂ gas is used as a purge gas. In addition, other inert gases such as argon (Ar) gas may be used as a carrier gas and a purge gas instead of N₂ gas. In addition, the shower head 13 configured to supply the purge gas as described above, the heater of the above-mentioned stage 12, and the exhaust mechanism 14 constitute a desorption mechanism for causing excess TMA gas on the wafer W to be desorbed in each etching method to be described later.

The etching apparatus 1 includes a controller 10, and the controller 10 includes a program. An instruction (each step) is incorporated in the program so that wafer W processing described later is performed. This program is stored in a computer storage medium (e.g., a compact disk, a hard disk, a magneto-optical disk, or a DVD) and installed in the controller 10. The controller 10 outputs a control signal to each part of the etching apparatus 1 according to the program, and controls the operation of each part. Specifically, the temperature of the wafer W by the heater of the stage 12, the supply/the stop of supply of respective gases to the shower head 13 by the gas supply devices 22A, 22B, 26A, and 26B, the pressure in the processing container 11 by the exhaust mechanism 14, and the like are controlled.

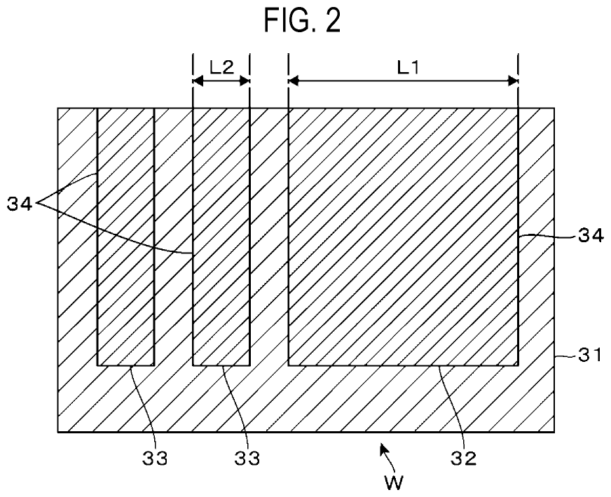

FIG. 2 illustrates an example of the surface of a wafer W to be processed by the etching apparatus 1. The first to third etching methods to be described later will be described with reference to a case where this wafer W is processed. A silicon nitride (SiN) film 31 is formed on the surface of the wafer W. The recesses 32 and 33 are formed in the SiN film 31 as patterns having widths different from each other. FIG. 2 illustrates a vertical cross section of the recesses 32 and 33, which are grooves, perpendicular to the extension direction thereof. That is, each of the recesses 32 and 33 extends in the front and rear direction of the paper surface.

The width of the recess 32 is larger than the width of the recesses 33. Therefore, the size of the opening of the recess 32 (=width L1) is larger than the size of the opening of the recess 33 (=width L2). The width L1 is, for example, 100 nm or more, and the width L2 is, for example, 100 nm or less. When the width L2 is within such a relatively small range, it is considered that blockage due to TMA, which will be described later, is likely to occur. The SiOₓ film 34 is embedded in the recesses 32 and 33, and the SiOₓ films 34 and the SiN film 31 are exposed on the surface of the wafer W.

### (First Etching Method)

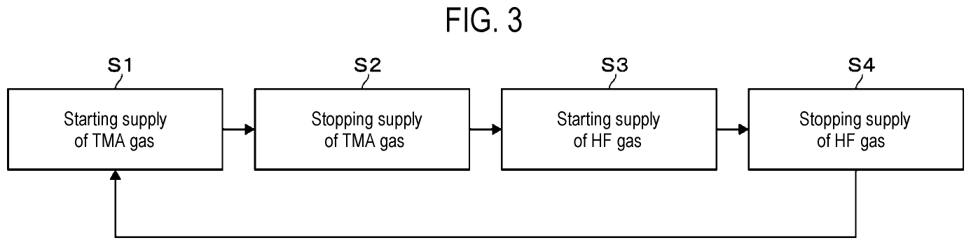

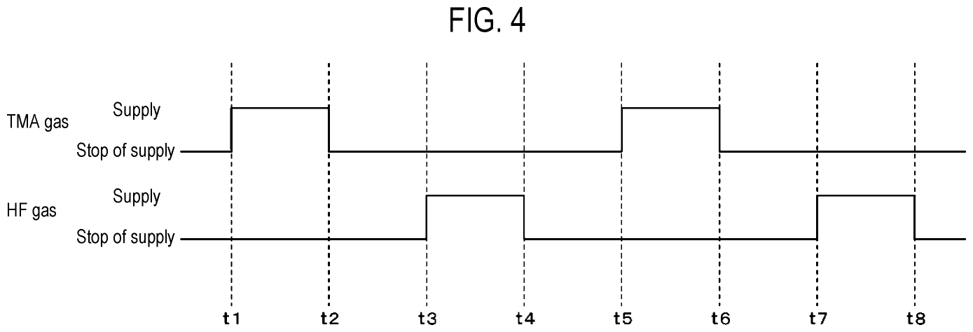

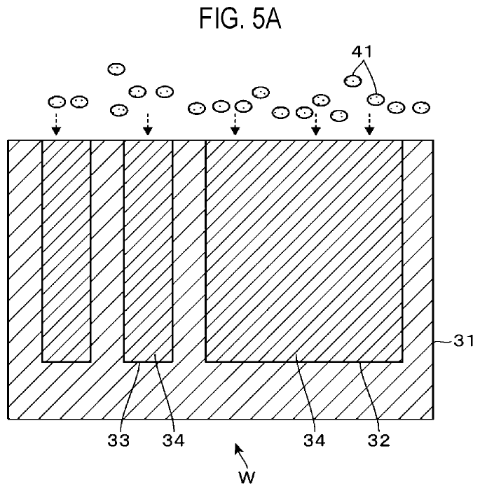

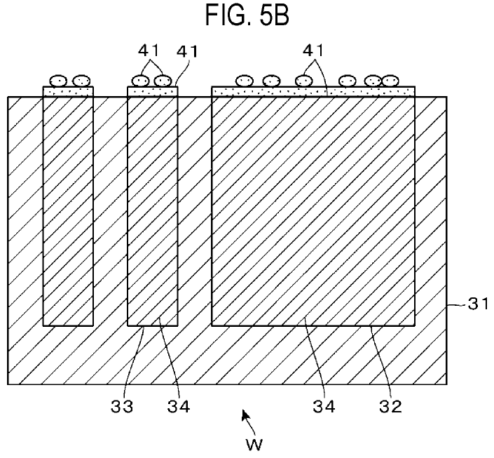

Subsequently, the first etching method according to an embodiment of the etching method of the present disclosure will be described with reference to FIG. 3, which is a flowchart illustrating a processing procedure, and FIG. 4, which is a timing chart illustrating the supply/the stop of supply of HF gas and TMA gas to the inside of the processing container 11. In addition, schematic views illustrating the surface states of the wafer W in FIGS. 5A to 10 will also be referred to as appropriate. In these schematic views, TMA gas is indicated as 41, and HF gas is indicated as 42.

First, the wafer W described with reference to FIG. 2 is placed on the stage 21 and heated to a preset temperature, and the inside of the processing container 11 is exhausted so as to have a preset pressure. The TMA gas 41 is supplied into the processing container 11 in the state in which the temperature of the wafer W and the pressure in the processing container 11 are controlled in this way (time t1, step S1). Since the TMA gas 41 has a high adsorption property to the SiOₓ films 34 and a low adsorption property to the SiN film 31, the TMA gas 41 is selectively adsorbed on the surfaces of the SiOₓ films 34 embedded in the recesses 32 and 33, respectively (FIGS. 5A and 5B). Thereafter, the supply of the TMA gas 41 into the processing container 11 is stopped (time t2, step S2), and the inside of the processing container 11 is purged using the purge gas.

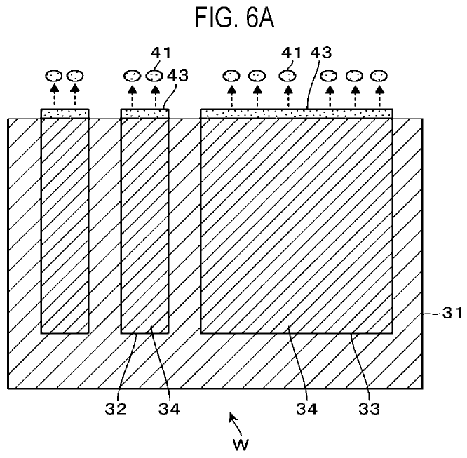

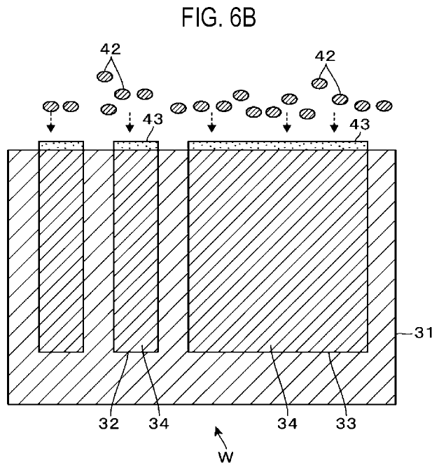

A part of the TMA gas 41 adsorbed on the wafer W is desorbed from the wafer W due to the supply of heat energy from the heated wafer W, and the actions of the exhaust and the purge gas within the processing container 11, and on the surface of the SiOₓ film 34 in each of the recesses 32 and 33, a TMA thin layer 43 is formed (FIG. 6A). The thin layer 43 is, for example, about one TMA molecular layer. That is, the thin layer 43 is a monomolecular layer or a layer in which several molecules are overlapped.

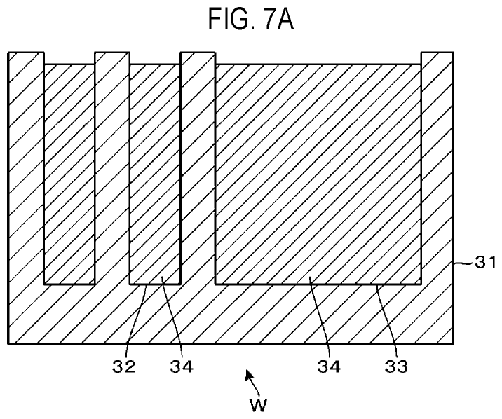

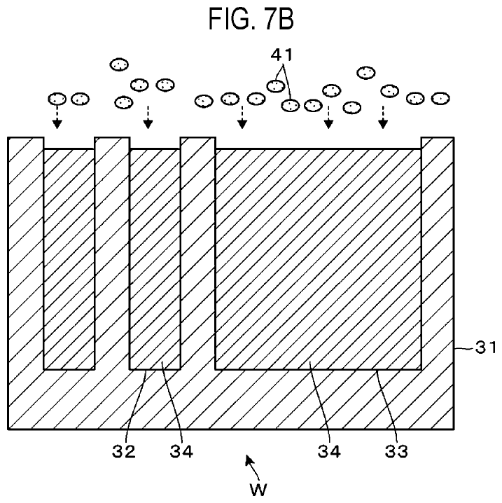

When a preset time elapses from time t2,the HF gas 42 is supplied into the processing container 11 (time t3, step S3). The HF gas 42 is activated by reacting with the TMA gas 41 forming the thin layer 43 on the SiOₓ film, the HF gas 42 thus activated reacts with the SiOₓ films 34, and the resulting reaction product sublimates. That is, the SiOₓ films 34 are etched (FIGS. 6B and 7A). Since the thickness of the thin layer 43 described above is extremely small, the etching amount (the etched film thickness) of each SiOₓ film 34 due to the above reaction is small. That is, the SiOₓ films 34 embedded in the recesses 32 and the SiOₓ film 34 embedded in the recess 33 are both etched little by little, and the etching amounts are the same. Then, as shown in the evaluation tests to be described later, the etching property of the HF gas 42 on the SiN film 31 is low. Therefore, among the SiN film 31 and the SiOₓ films 34, the SiOₓ films 34 are selectively etched.

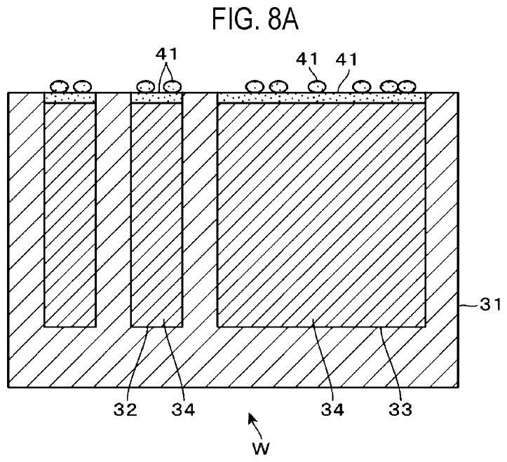

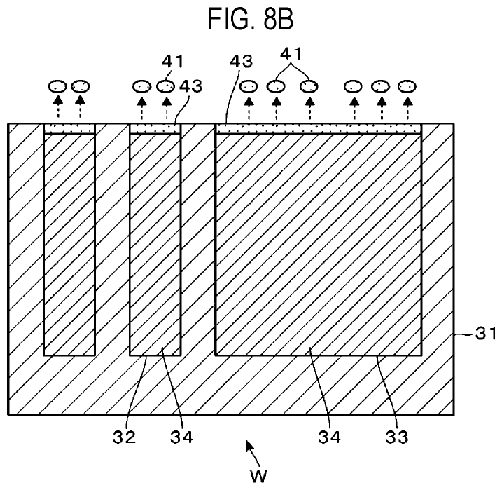

When a preset time elapses from time t3, the supply of the HF gas 42 into the processing container 11 is stopped (time t4, step S4), and the HF gas 42 remaining in the container 11 is purged by the purge gas supplied into the processing container 11. Then, after a lapse of a preset time from the time t4, the TMA gas 41 is supplied into the processing container 11 (time t5) and is selectively adsorbed on the surfaces of the SiOₓ film 34 etched from time t3 to time t4 described above (FIGS. 7B and 8A), after which the supply of the TMA gas 41 into the processing container 11 is stopped (time t6). That is, the above-described steps S1 and S2 are executed again.

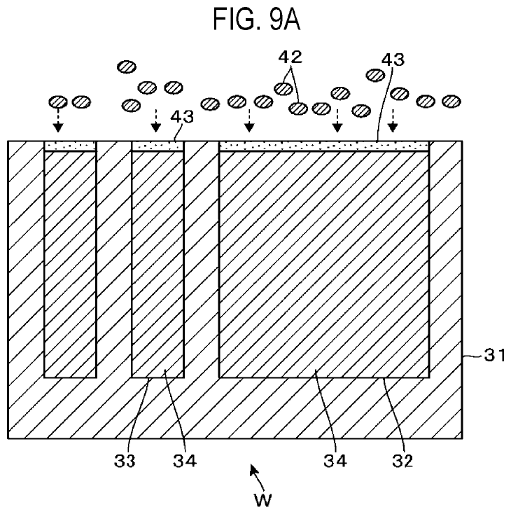

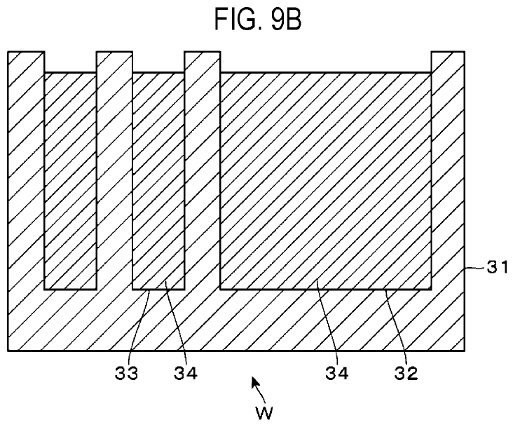

After the supply of the TMA gas 41 at time t6 is stopped, the inside of the processing container 11 is purged by the purge gas, and a part of the TMA gas 41 adsorbed on the SiOₓ films 34 is desorbed by the purge gas, the exhaust, and the supply of heat from the wafer W as in the period from time t2 to time t3. Then, a TMA thin layer 43 is formed again on the surface of each SiOₓ film 34 (FIG. 8B), and then the HF gas 42 is supplied into the processing container 11 (time t7). That is, step S3 is executed again, and each SiOₓ film 34 is etched (FIGS. 9A and 9B). Even during this re-etching, since the TMA gas 41 is adsorbed on the surface of each SiOₓ film 34 and a thin layer 43 is formed on the surface of each SiOₓ film 34, each of the SiOₓ films 34 in the recesses 32 and 33 is selectively etched with high uniformity such that the film thickness is reduced. Thereafter, the supply of the HF gas 42 into the processing container 11 is stopped (time t8). That is, step S4 is executed again.

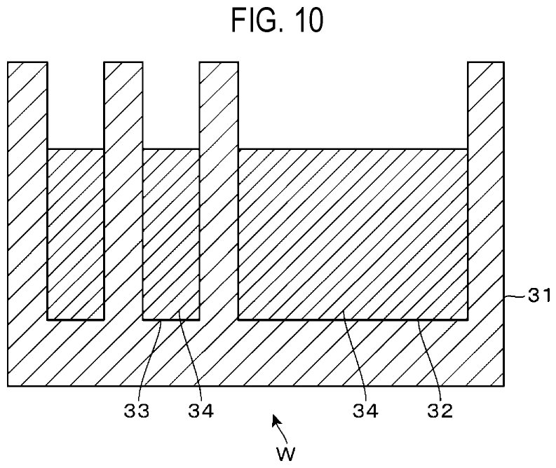

For example, even thereafter, a cycle including steps S1 to S4 is repeated, an adsorption step causing TMA gas 41 to be selectively adsorbed on the SiOₓ films 34, a desorption step for causing excess TMA gas 41 to be desorbed from the SiOₓ films 34, and an etching step for etching the SiOₓ films 34 by HF gas 42 is repeated in order. As a result, selective etching of the SiOₓ films 34 proceeds in each in-plane portion of the wafer W with high uniformity and little by little. Then, when the above cycle is repeated a preset number of times, the processing on the wafer W is completed, and the wafer W is carried out from the processing container 11. Since the etching proceeded on the processed wafer W as described above, the uniformity in the etching amount of the SiOₓ films 34 in the recesses 32 and 33 is high, and a SiOₓ film 34 having a desired thickness remains in each of the recesses 32 and 33 (FIG. 10).

It has been described that the TMA gas is desorbed from the wafer W while the supply of the TMA gas and the HF gas is stopped. However, as described above, since the heat supply from the wafer W and the exhaust within the processing container 11 contribute to the desorption, such desorption also occurs, for example, when the TMA gas is supplied to the wafer W. That is, the step of desorption of the TMA gas from the wafer W is not limited to being performed at a time different from the time at which the TMA gas adsorption step is performed, and may be performed in parallel with the adsorption step.

In addition, the thin layer 43 at the time of supplying the HF gas is not limited to the above-mentioned monomolecular layer or a structure in which several molecules are stacked, and may be formed as a thicker layer, the thickness of which is optional. Since it is possible to change the adsorbed amount of the TMA gas by controlling the processing conditions such as the amount of TMA gas supplied to the wafer W and the temperature of the wafer W, it is possible to adjust the thickness of the thin layer 43 by changing the processing conditions.

In the above-described processing example, it has been described that the cycle including steps S1 to S4 is repeated twice or more, but the number of repetitions of this cycle may be two. In addition, the number of cycles may be one, that is, the steps S1 to S4 may be performed only once without repeating.

### (Second Etching Method)

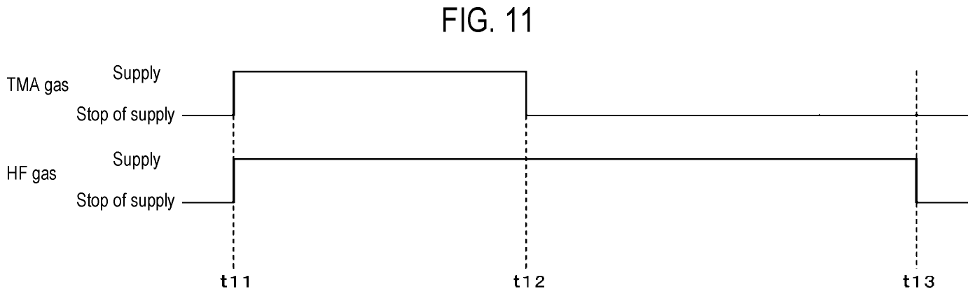

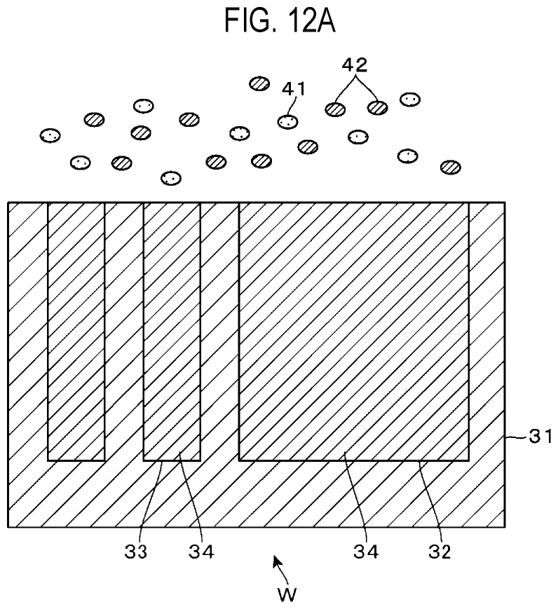

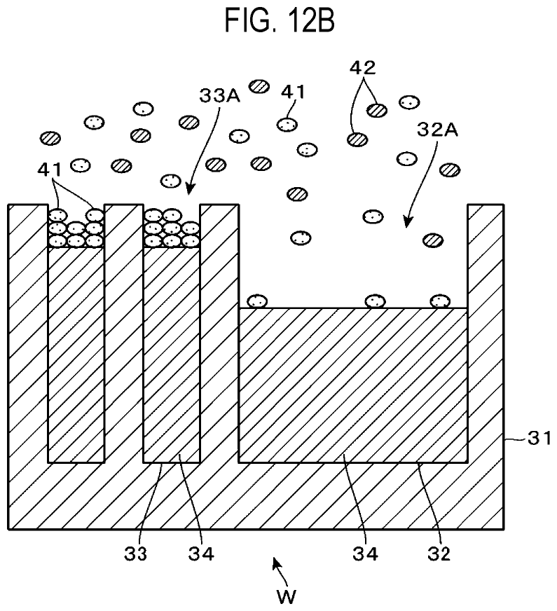

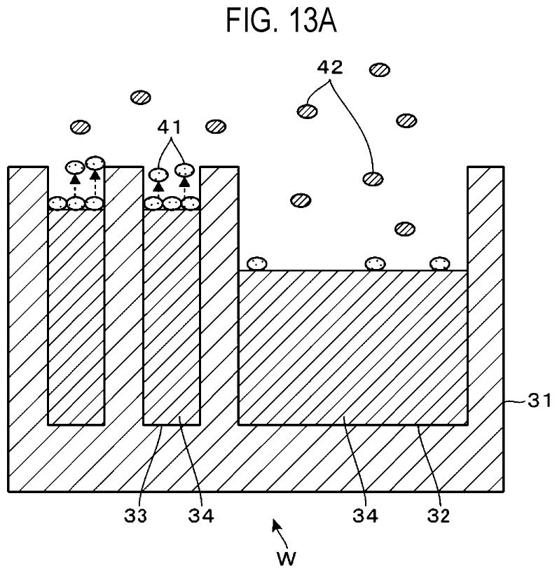

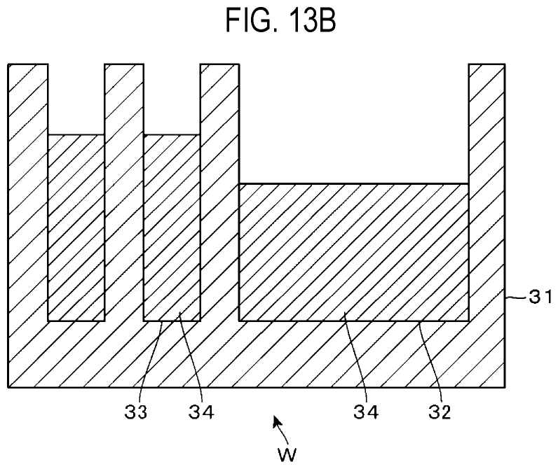

Regarding the second etching method, with reference to FIG. 11, which is a timing chart illustrating the supply/the stop of supply of TMA gas 41 and HF gas 42 into the processing container 11, and FIGS. 12A to 13B, which illustrate the surface states of a wafer W, the difference from the first etching method will be mainly described. The wafer W described with reference to FIG. 2 is placed on the stage 21 and heated to a preset temperature, and the inside of the processing container 11 is exhausted so as to have a preset pressure. In that state, TMA gas 41 and HF gas 42 are supplied into the processing container 11 (FIG. 12A, time t11).

The TMA gas 41 is adsorbed on the surface of each of the SiOₓ films 34 in the recesses 32 and 33. Since both the TMA gas 41 and the HF gas 42 are supplied together, the HF gas 42 rapidly reacts with the TMA gas 41 adsorbed in this way, and the surfaces of the SiOₓ films 34 are etched. Then, the TMA gas 41 is newly adsorbed on the surfaces of the etched SiOₓ films 34 and reacts with the HF gas 42, so that the surfaces of the SiOₓ films 34 are further etched (FIG. 12B). Then, when a preset time elapses from the start of the supply of the TMA gas 41 and the HF gas 42, the supply of the TMA gas 41 is stopped, while the supply of the HF gas 42 into the processing container 11 is continued. (FIG. 13A, time t12).

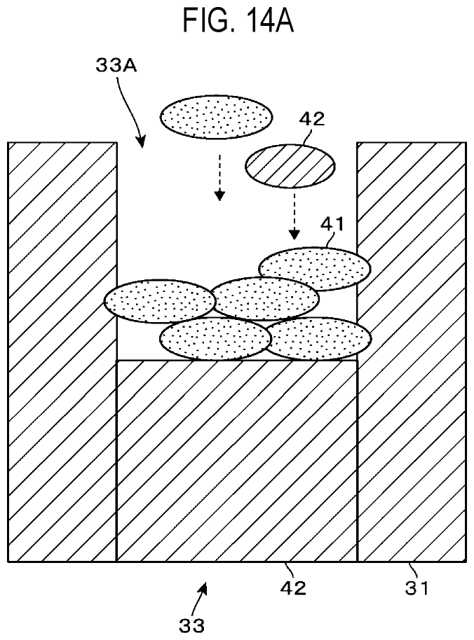

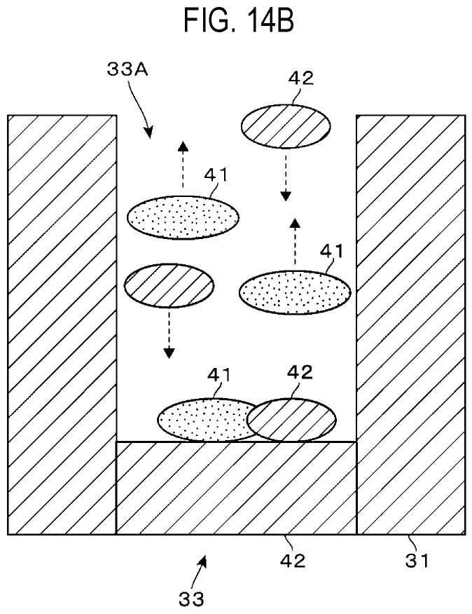

The reason for changing the TMA gas 41 and the HF gas 42 such that the HF gas 42 is applied alone as described above will be described. In the description, FIGS. 14A and 14B, which are schematic views illustrating the states considered to occur in the recesses 33 of the SiN film 31, will also be referred to. FIG. 14A illustrates the state immediately before the supply of the TMA gas 41 is stopped, and FIG. 14B illustrates the state after the supply of the TMA gas 41 is stopped.

Until the supply of the TMA gas 41 is stopped, the etching of the SiOₓ films 34 proceeds in the recesses 32 and 33 in the SiN film 31, as described above. Thus, the heights of the surfaces of the SiOₓ films 34 decrease, and the depths of the grooves having the surfaces of the SiOₓ films 34 as the bottom surfaces increase. Regarding the grooves, the bottom surfaces of which are the SiOₓ films 34, the groove formed in the recess 32 will be referred to as a “groove 32A”, and the groove formed in the recess 33 will be referred to as a “groove 33A”.

When the depths of the grooves 32A and 33A increase in this way, the TMA gas 41 and the HF gas 42 are likely to flow into the groove 32A since the opening width of the groove 32A is wide. Therefore, the etching of the SiOₓ film 34 continues. Meanwhile, since the opening width of the groove 33A is narrow, it is difficult for the TMA gas 41 and the HF gas 42 to flow into the groove 33A. However, since the TMA gas 41 has a high adsorption property to the SiOₓ film 34 as described above, the TMA gas 41 that has once entered the groove 33A is easily adsorbed on the surface of the SiOₓ film 34 and stays there as illustrated in FIG. 14A, and the molecules of the TMA gas 41 are further adsorbed and deposited on the molecules of the adsorbed TMA gas 41.

As a result, the amount of TMA molecules deposited on the SiOₓ film 34 of the groove 33A increases, and the groove 33A is closed. As a result, the supply of the HF gas 42 to the surface of the SiOₓ film 34 is hindered. That is, the HF gas 42 reacts with the TMA gas 41 adsorbed on the surface of the SiOₓ film 34, and is not able to etch the SiOₓ film 34. Therefore, the etching of the SiOₓ film 34 is stopped or the etching rate is lowered in the recesses 33.

Therefore, as described above, at time t12, the supply of only the TMA gas 41 among the TMA gas 41 and the HF gas 42 is stopped. After the supply of the TMA gas 41 is stopped, the TMA gas 41 is gradually desorbed from the surface of the SiOₓ film 34 in the groove 33A by the exhaust within the processing container 11, the application of heat energy from the wafer W, and the purging action of the HF gas 42. Meanwhile, the HF gas 42, which is being continuously supplied, is able to enter the groove 33A and react with the TMA gas 41 directly adsorbed on the surface of the SiOₓ film 34 due to the occurrence of the above-mentioned desorption. That is, the etching of the SiOₓ film 34 is restarted in the recesses 33. In this way, after the supply of the TMA gas 41 is stopped, the etching of the SiOₓ film 34 proceeds by the remaining TMA gas 41 and the newly supplied HF gas 42 in the recesses 33.

In the case where the TMA gas 41 is adsorbed and remains on the surface of the SiOₓ film 34 even in the groove 32A when the supply of the TMA gas 41 is stopped at time t12, the SiOₓ film 34 in the groove 32A is etched by the HF gas supplied after time t12 and the corresponding TMA gas 41. When a preset time elapses from time t12, the supply of the HF gas 42 into the processing container 11 is stopped (time t13), and the etching process is completed (FIG. 13B).

As described above, according to the second etching method, first, the adsorption step and the etching step are performed in parallel by the TMA gas 41, and after time t12 at which the supply of the TMA gas is stopped, the desorption step and the etching step are performed in parallel by the excess TMA gas 41. As a result, it is possible to prevent the etching of the SiOₓ film 34 from stopping due to excessive retention of the TMA gas 41 in the recesses 33 having a relatively narrow opening width. Therefore, since it is possible to etch the SiOₓ films 34 in the recesses 33 more deeply, it is possible to form the SiOₓ films at a desired film thickness.

### (Third Etching Method)

In the second etching method described above, FIG. 13B illustrates that at the end of etching, the etching amounts of the SiOₓ film 34 are different between the recess 32 and the recesses 33, but the etching amounts may be made to be equal to each other. In this third etching method, for example, similarly to the second etching method, the wafer W described with reference to FIG. 2 is processed by supplying each of the TMA gas 41 and the HF gas 42 into the processing container 11 according to the timing chart described with reference to FIG. 11.

Therefore, in this third etching method, the TMA gas 41 and the HF gas 42 are started to be supplied to the wafer W at time t11 (FIG. 12A). Then, after the etching proceeds in each of the SiOₓ films 34 in the recesses 32 and 33 by the TMA gas 41 and the HF gas 42 as described above, the TMA gas 41 stays on the SiOₓ films 34 in the recesses 33 having a narrow opening width so that TMA molecules are deposited and etching stops. Meanwhile, since both the TMA gas 41 and the HF gas 42 easily enter the recess 32 due to the wide opening width of the recess 32, the etching of the SiOₓ film 34 proceeds. As a result, as illustrated in FIG. 12B, the etching amount in the recess 32 is larger than the etching amount in the recesses 33.

Thereafter, the supply of TMA gas 41 is stopped at time t12. When the supply of the TMA gas 41 is stopped, the TMA gas 41 is consumed because the etching has been continuously performed up to that point in the recess 32. Thus, the amount of the TMA gas 41 adsorbed on the SiOₓ film 34 is relatively small. Therefore, after the supply of the TMA gas 41 is stopped, the etching amount of the SiOₓ film 34 in the recess 32 is zero to a very small amount.

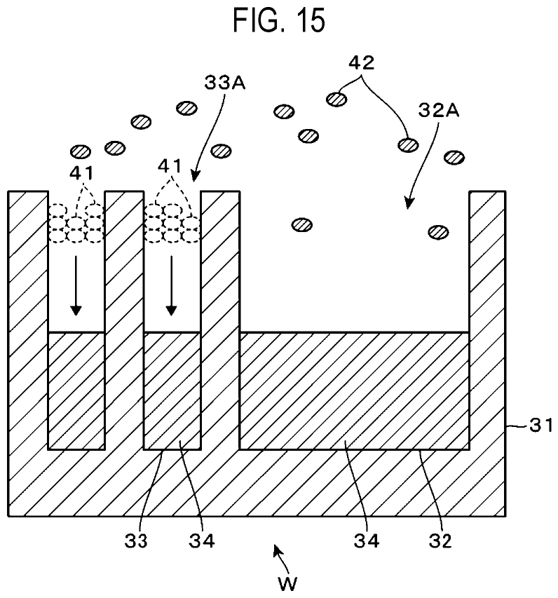

Meanwhile, as described in the description of the second etching method, a large amount of TMA gas 41 is adsorbed on the SiOₓ films 34 in the recesses 33 at time t12. Then, after time t12, the etching of the SiOₓ films 34 is restarted since the desorption of the TMA gas 41 proceeds. However, even if the desorption proceeds to some extent, since a large amount of TMA gas 41 has been originally adsorbed on the SiOₓ films 34, the etching amount after time t12 becomes relatively large. As a result, when the supply of the HF gas 42 is stopped at time t13, the etching amounts of the SiOₓ film 34 become equal to each other between the recess 32 and the recesses 33, as illustrated in FIG. 15.

As described above, according to the third etching method, the etching amounts of the SiOₓ films 34 are made to be equal to each other between the recesses 32 and 33 having different opening widths using the difference in the adsorption amount of the TMA gas 41 between the recesses 32 and 33 when the supply of the TMA gas is stopped. The amount of TMA gas 41 adsorbed on the SiOₓ films 34 of the recesses 32 and 33 when the supply of TMA gas 41 is stopped may be controlled by appropriately setting various processing conditions, such as the flow rate of TMA gas 41 and the temperature of the wafer W. However, although this third etching method has been described assuming that the etching amounts of the SiOₓ films 34 are made to be equal to each other between the recesses 32 and 33, various processing conditions may be set such that a desired difference occurs in the etching amounts.

Meanwhile, in the second and third etching methods, it has been described that, before time t12 at which the supply of HF gas alone is started, a difference is caused in the adsorption amount of the TMA gas 41 between the recess 32 and the recesses 33 by supplying the TMA gas 41 and the HF gas 42 at the same time. However, even if the TMA gas 41 and the HF gas 42 are sequentially supplied as in the first etching method, a relatively large amount of the TMA gas 41 is adsorbed in the recesses 33 depending on the processing conditions, such as the flow rate of the TMA gas 41, and thus a difference is caused between the recesses 32 and 33. That is, in the second etching method and the third etching method described above, the TMA gas 41 and the HF gas 42 may be sequentially supplied before time t12. Therefore, the present disclosure is not limited to supplying these gases at the same time. However, supplying these gases at the same time is desirable because it is possible to shorten the etching time.

Exemplary processing conditions for performing the first to third etching methods described above will be presented. The pressure in the processing container 11 is 0.13332 Pa to 13332 Pa. The flow rate of the HF gas supplied into the processing container 11 is 0.1 sccm to 2000 sccm, the flow rate of the TMA gas supplied into the processing container 11 is 0.1 sccm to 1000 sccm, and the flow rate of the N₂ gas supplied into the processing container 11 is 0.1 sccm to 2000 sccm. The temperature of the wafer W is −50 degrees C. to 200 degrees C. By processing the wafer W at such a temperature, it is possible to perform the adsorption of the gas of an organic amine compound such as TMA and the etching of SiOₓ (that is, sublimation of the reaction product). That is, the first to third etching methods described above are preferable because it is not necessary to change the temperature of the wafer W during the processes described in the first to third etching methods.

It has been described that the film for forming the recesses 32 and 33 in which the SiOₓ films 34 are embedded is composed of SiN. However, the film is not limited to being composed of SiN, and may be composed of other silicon-containing materials. The film may be composed of, for example, Si, silicon carbide (SiC), SiOC, SiCN, and SiOCN. Even in that case, it is possible to selectively etch the SiOₓ films 34 since the TMA gas is selectively adsorbed on the SiOₓ films 34. In addition, as the oxygen-containing silicon film that is selectively etched with respect to the recesses 32 and 33, in addition to the SiOₓ film, a SiOCN film to be described later, tetraethyl orthosilicate (TEOS) illustrated in the evaluation tests to be described, and the like may be used. Therefore, the oxygen-containing silicon film is not limited to the SiOₓ film. In addition, containing oxygen does not mean that the oxygen is contained as an impurity, but means that oxygen is contained as a main component constituting the film.

An example in which trimethylamine (TMA) gas is used as the organic amine compound gas has been illustrated, but the gas is not limited to the TMA gas, and a known organic amine compound gas may be used. Specifically, for example, gases of organic amine compounds, such as monomethylamine, dimethylamine, dimethylethylamine, diethylmethylamine, monoethylamine, diethylamine, triethylamine, mononormalpropylamine, dinormalpropylamine, monopropylamine, monoisopropylamine, diisopropylamine, monobutylamine, dibutylamine, mono(tert-butyl)amine, di(tert-butyl)amine, pyrrolidine, piperidine, piperazine, pyridine, and pyrazine, may be used.

In addition, as another specific example of the organic amine compound, compounds obtained by substituting some or all of the C—H bonds of the above-mentioned components with C—F bonds (e.g., trifluoromethylamine, 1,1,1-trifluorodimethylamine, perfluorodimethylamine, 2,2,2-trifluoroethylamine, perfluoroethylamine, bis(2,2,2-trifluoroethyl)amine, perfluorodiethylamine, and 3-fluoropyridine) may be used. These organic amine compounds are preferable in that they have a conjugated acid pKa of 3.2 or more of HF, are capable of forming a salt with HF, have a constant vapor pressure in a temperature range of 20 to 100 degrees C., and are not decomposed in this temperature range to be capable of being supplied as a gas.

In addition, as the etching gas, a halogen-containing gas may be used, and a gas of a compound, such as HCl, HBr, HI, or SF₄, may be used, in addition to HF containing fluorine as halogen. Although it has been described in FIG. 2 that the recesses in the SiN film in which SiOₓ is embedded are grooves, the recesses may be holes. That is, this technique is also applicable even when a plurality of holes having different opening diameters (=opening sizes) are provided in the SiN film and the SiOₓ film embedded in each hole is selectively etched.

It should be noted that the embodiments disclosed herein are exemplary in all respects and are not restrictive. The above-described embodiments may be omitted, replaced, modified, and/or combined in various forms without departing from the scope and spirit of the appended claims.

Next, evaluation tests conducted in connection with this technique will be described.

### Evaluation Test 1

As Evaluation Test 1, the adsorption energy for each of a SiN film and a SiOₓ film for TMA in the range of −50 degrees C. to 200 degrees C. was measured by simulation. The lower the adsorption energy, the more stable the TMA molecules is, that is, the easier TMA molecules are to be adsorbed.

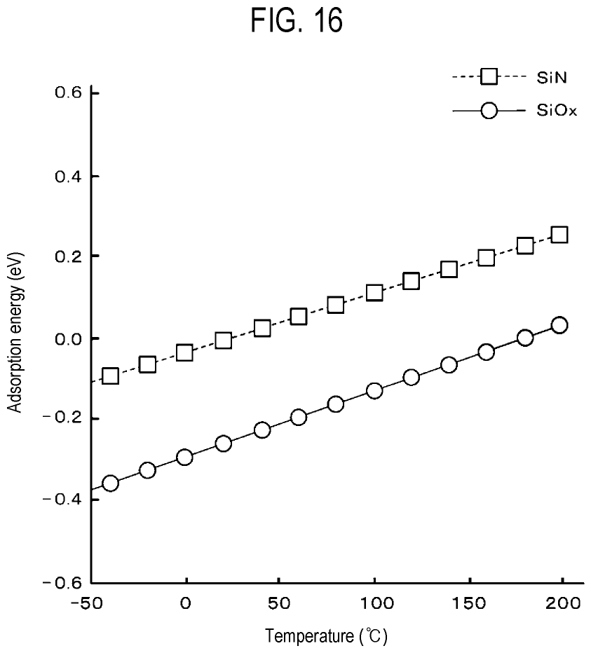

FIG. 16 is a graph showing the results of Evaluation Test 1. In the graph, the horizontal axis represents temperature (unit: ° C.) and the vertical axis represents adsorption energy (unit: eV). As shown in this graph, when the adsorption energy for the SiOₓ film and the adsorption energy for the SiN film at the same temperature are compared, the adsorption energy for the SiOₓ film is lower.

As shown in the graph, the value of the adsorption energy of each of the SiN film and the SiOₓ film increases as the temperature rises, but the adsorption energy of the SiOₓ film had a value slightly higher than 0 eV even at 200 degrees C. That is, it can be seen that TMA has a high adsorption property to SiOₓ in the temperature range in Evaluation Test 1 (−50 degrees C. to 200 degrees C.). Therefore, from the results of Evaluation Test 1, it was confirmed that TMA is selectively adsorbed on the SiOₓ film among the SiN film and the SiOₓ film in the range of −50 degrees C. to 200 degrees C. It is considered that these results were obtained due to the formation of hydrogen bonds between the nitrogen atoms of the TMA and the hydrogen atoms (existing by bonding with the oxygen atoms) in the SiOₓ film, and occurrence of dipole interaction between polarized TMA and polarized SiOₓ. It is considered that organic amines other than TMA are also selectively adsorbed on the SiOₓ film for the same reason.

### Evaluation Test 2

As Evaluation Test 2, an etching process was performed by supplying TMA gas and HF gas to each of the SiOₓ film and SiN film formed on a substrate. This etching process was performed on a plurality of substrates, and the combination of the pressure in the processing container 11 and the supply time of each gas was changed for each process. Then, the etching amount of each film was measured for the processed substrates, and the etching amount of the SiOₓ film/the etching amount of the SiN film was calculated as an etching selectivity.

The SiOₓ film was formed through a heating process of Si in an oxygen-containing atmosphere, and the SiN film was formed through ALD. The pressure in the processing container 11 was set to 2.1 Torr (280 Pa), 3 Torr (400 Pa), or 4 Torr (533.2 Pa), and the supply time for each gas was 5 sec, 10 sec, or 30 sec. Then, each etching process was performed by setting the temperature of each wafer W to 140 degrees C.

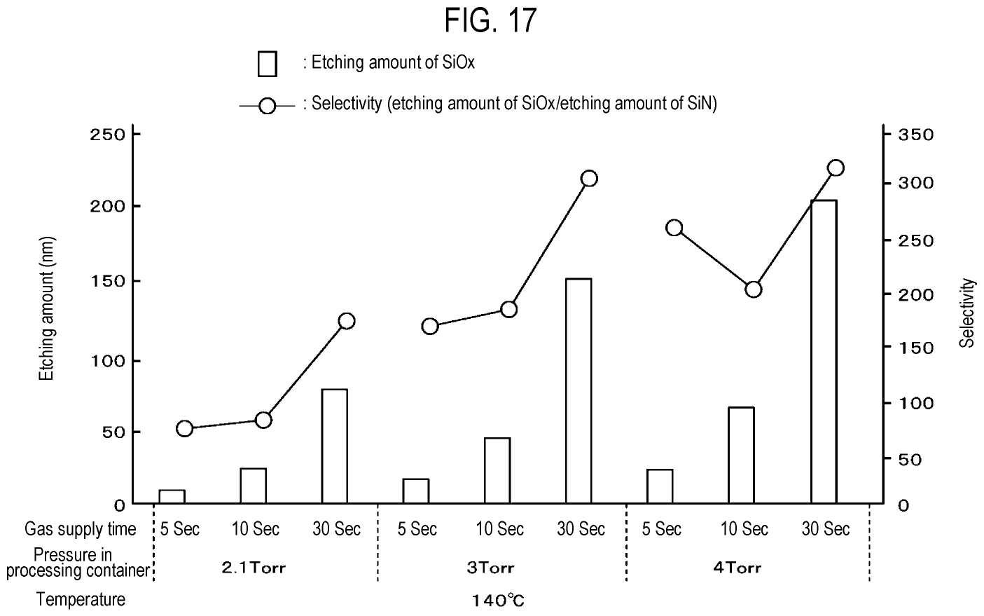

The results of Evaluation Test 2 are shown in FIG. 17. In FIG. 17, the bar graph represents etching amounts of SiOₓ films, and the line graph represents etching selectivities. In each etching process, the etching amounts of SiN films were extremely small (less than 1 nm), and thus are not shown in the graph. As is clear from the graphs, the etching amounts and the etching selectivities of the SiOₓ films were relatively large values regardless of the combination of the supply time of each gas and the pressure in the processing container 11. In addition, it can be seen from the graphs that the higher the pressure in the processing container 11, the etching amount of the SiOₓ film tends to increase, and therefore the etching selectivity also increases. Specifically, when the pressure in the processing container 11 was 4 Torr and the supply time of the gas was 30 sec, the etching amount of SiOₓ was 205 nm, and the etching selectivity was 316. That is, the largest value was obtained for each of the etching amount and the etching selectivity.

From the results of Evaluation Test 2, it can be seen that when etching a SiOₓ film using HF gas, it is possible to selectively etch SiOₓ film with respect to the SiN film by supplying TMA gas. In addition, from the results of Evaluation Test 2, it was confirmed that it is possible to etch SiOₓ at a temperature at which TMA gas is adsorbed. That is, it was confirmed that it is not necessary to switch the temperature of the wafer W between when TMA is adsorbed and when the reaction product produced through the reaction of TMA, HF gas and SiOₓ is sublimated.

### Evaluation Test 3

As Evaluation Test 3, each of an SiOₓ film and a TEOS film formed on a substrate was etched by supplying TMA gas and HF gas according to the cycle of FIG. 3 described in the first etching method described above. The number of cycles was changed for each etching process. The SiOₓ film was formed through a heating process of Si in an oxygen atmosphere, similar to the SiOₓ film in Evaluation Test 2.

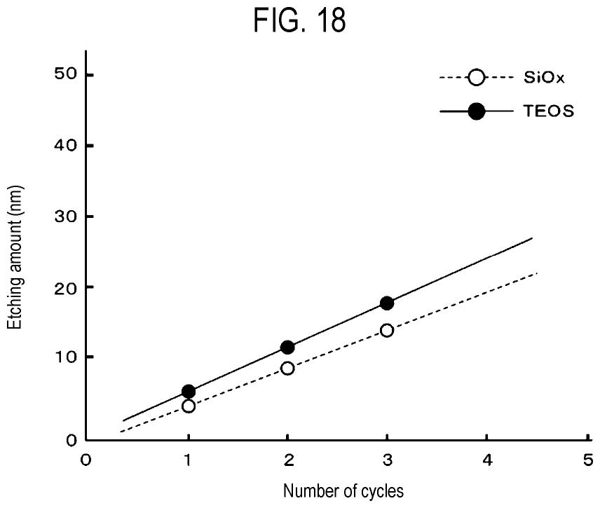

The graph of FIG. 18 shows the results of Evaluation Test 3, and the horizontal axis and the vertical axis of the graph represent the number of cycles and the etching amount (unit: nm), respectively. As shown in the graph, the number of cycles and the etching amount are approximately proportional to each other for each of the SiOₓ film and the TEOS film, and the etching amount in one cycle is about 5 nm for the SiOₓ film and about 6 nm for the TEOS film. As described above, the etching amount of each of the SiOₓ film and the TEOS film in one cycle was at an atomic layer level.

As described above, from the results of Evaluation Test 3, it was confirmed that it is possible to etch an oxygen-containing silicon film at the atomic layer level by performing the cycle described in the first etching method and it is possible to control the oxygen-containing silicon film so as to obtain a desired etching amount by repeatedly performing the cycle. Therefore, as described as the first etching method, it is considered that it is possible to set the etching amount of the oxygen-containing silicon film in each in-plane portion of a wafer W to a desired value and to make the etching amount highly uniform in the plane of the wafer W.

### Evaluation Test 4

On a substrate including a SiN film in which a recess as a groove was formed and a SiOₓ film was embedded in the recess, the SiOₓ film was etched. Then, the vertical cross-sectional surface of the substrate after the etching process was imaged, and the depth of a groove formed through the etching (=the etching amount of the SiOₓ film) was measured. In addition, the width of the opening of the recess is 1 nm.

In Evaluation Test 4, the above etching was performed while changing the gas supply method for each substrate. For one substrate, HF gas and TMA gas were simultaneously supplied to the wafer W as in the period from time t11 to time t12 in the timing chart of FIG. 11. However, the supply of HF gas alone was not performed after time t12 in this timing chart. The test conducted by supplying each gas in this way will be referred to as Evaluation Test 4-1.

For the other substrates, the gases were supplied as illustrated in the timing chart of FIG. 11. That is, after supplying HF gas and TMA gas at the same time, the supply of HF gas alone was performed. Etching was performed under the same processing conditions as in Evaluation Test 4-1, except that the supply of HF gas alone was performed. The test conducted by supplying each gas in this way will be referred to as Evaluation Test 4-2.

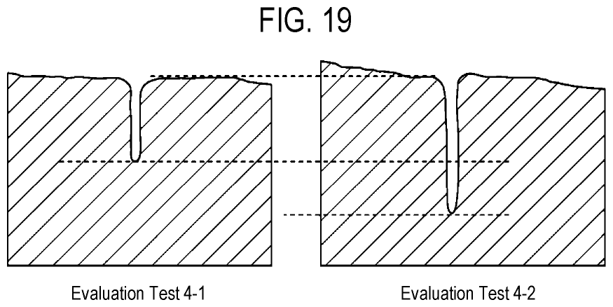

FIG. 19 is a schematic view illustrating images obtained from the substrates in Evaluation Tests 4-1 and 4-2. The depths of grooves formed in Evaluation Test 4-1 and Evaluation Test 4-2 were 21 nm and 36 nm, respectively. That is, the depth of the groove in Evaluation Test 4-2 was larger. It is considered that, in Evaluation Test 4-1, etching was stopped because HF gas was not supplied to the SiOₓ film after the adsorption of TMA gas proceeded and TMA molecules were excessively deposited. Meanwhile, it is considered that, in Evaluation Test 4-2, etching proceeded more than that in Evaluation Test 4-1 because, after the supply of TMA gas was stopped, the desorption of the TMA gas from the wafer W proceeded and thus HF gas was supplied to the SiOₓ film as described in the second etching method. Therefore, according to Evaluation Test 4, it was confirmed that it is possible to increase the etching amount by supplying TMA gas and HF gas and then supplying HF gas alone.

### Evaluation Test 5

As Evaluation Test 5-1, the cycle including steps S1 to S4 described in FIGS. 3 and 4 was performed 5 times on a substrate having a SiOₓ film formed on the surface thereof. Therefore, in one cycle, HF gas was supplied after supplying TMA gas, and in repeating the cycle, during the supply of the TMA gas and the supply of HF gas, purge gas was supplied into the processing container that stores the substrate and the processing container was exhausted. The time of one cycle was 30 seconds, and the temperature of the substrate during processing was 40 degrees C. After such etching, water was supplied to the surface of the processed substrate, and thus the components contained in the substrate were eluted into the water. Then, the fluorine content in the water was measured using an ion chromatography method.

As Evaluation Test 5-2, a substrate having a SiOₓ film formed on the surface thereof was processed with TMA gas and HF gas, and the fluorine content in the water supplied to the surface of the processed substrate was measured using an ion chromatograph method, as in Evaluation Test 5-1. Evaluation Test 5-2 may be said to be different from Evaluation Test 5-1 in that TMA gas and HF gas were simultaneously supplied to the substrate for 4 seconds. In both Evaluation Tests 5-1 and 5-2, the etching process was performed in the state in which the substrate temperature was set to a temperature within the range described above.

In Evaluation Test 5-1, the fluorine content was 3.0×10¹⁴ atoms/cm², and in Evaluation Test 5-2, the fluorine content was 5.8×10¹⁴ atoms/cm². As described above, Evaluation Test 5-1 had a smaller value for the fluorine content. Therefore, from Evaluation Test 5, it can be seen that it is possible to suppress the amount of halogen remaining on the etched substrate to a low level by etching the oxygen-containing silicon film by supplying an halogen-containing etching gas subsequent to an organic amine compound gas. It is considered that the above test results were obtained by suppressing permeation of HF gas supplied later into the substrate by forming a protective film on a SiOₓ film since the organic amine compound has a relatively high adsorptivity to the SiOₓ film, as described above.

In Evaluation Test 5, TMA gas, that is, an organic amine compound gas in which amino groups are bonded to branched alkyl groups was used as the organic amine compound gas, but it is more preferable to use an organic amine gas in which amino groups are bonded to branchless linear alkyl groups. Concerning the reason for this, it is considered that the organic amine compound is adsorbed on the oxygen-containing silicon film since the amino groups in the organic amine compound are adsorbed on the oxygen-containing silicon film. Assuming that the organic amine compound is composed of branched alkyl groups, it may be considered that the side chains of the alkyl groups interfere with the film, which prevents the amino groups in the same molecules as the alkyl groups from coming into contact with the film. In addition, assuming that a large number of molecules of the organic amine compound are adsorbed on a film, the side chains of the molecules interfere with each other. It may be considered that the number of molecules of the organic amine compound adsorbed per unit area of the film is relatively small so that the interference does not occur, and the gaps between the molecules are relatively large.

However, when the organic amine compound having linear alkyl groups is used, there are no chains of alkyl groups. Therefore, inhibition of the adsorption of amino groups to the film by side chains and interference between side chains of molecules do not occur. Therefore, it is considered that, since the molecules of the organic amine compound are more reliably and densely adsorbed on the oxygen-containing silicon film, it is possible to more reliably obtain the effect as a protective film that suppresses the permeation of halogen into the substrate.

As described above, since the amino groups are adsorbed on the film, the linear alkyl groups extend toward the opposite side of the film when viewed from the amino groups. Therefore, the linear alkyl group becomes longer as the number of carbons increases, and when viewed as the protective film, the linear alkyl group is more preferable because the linear alkyl group is thick and thus the function thereof as the protective film is enhanced. From the foregoing, as the organic amine compound gas, it is preferable to use an organic amine compound having a linear alkyl group represented by CₙH₂ₙ₊₁, wherein n, which indicates the number of carbon atoms in CₙH₂ₙ₊₁₊₁, is an integer of 4 or more. Specifically, for example, it is preferable to use butylamine, hexylamine, octylamine, decylamine, or the like.

Even if the alkyl group has a branched structure, it is considered that the permeation of halogen can be sufficiently prevented if the n (=the number of carbons) is relatively large. In addition to octylamine and decylamine having a linear alkyl group taken as specific examples, for example, decylamine having a branched alkyl group represented by the following Molecular Formula 1 is known to have a relatively high anti-corrosion property, i.e., high protective performance, with respect to a metal surface. Therefore, even when decylamine having a branched alkyl group is used as a protective film against the oxygen-containing silicon film, it is considered that the permeation can be sufficiently prevented. Therefore, for example, n is more preferably an integer of 10 or more. Each amine described above may be used in each etching method described in the embodiments. Therefore, while obtaining the effects described in each embodiment, it is possible to suppress a residual halogen, such as fluorine, in a processed wafer W so as to suppress the influence of the halogen on a post-etching process of the wafer W.

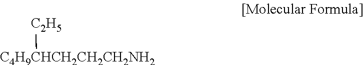

According to the present disclosure, when etching oxygen-containing silicon films embedded in a plurality of recesses having different opening widths in a substrate, it is possible to improve the controllability of the etching amount in each in-plane portion of the substrate.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. An etching method of etching an oxygen-containing silicon film embedded in each recess of a substrate, which includes a plurality of recesses having different opening sizes, by supplying an etching gas to the substrate, the etching method comprising:
adsorbing an organic amine compound gas on the oxygen-containing silicon film by supplying the organic amine compound gas to the substrate;
desorbing an excess of the organic amine compound gas from the substrate; and
selectively etching the oxygen-containing silicon film with respect to each recess by supplying the etching gas containing a halogen to the substrate on which the organic amine compound has been adsorbed.

2. The etching method of claim 1, wherein the adsorbing the organic amine compound gas and the selectively etching the oxygen-containing silicon film are performed at different timings.

3. The etching method of claim 2, wherein a cycle including the adsorbing the organic amine compound gas, the desorbing the excess of the organic amine compound gas, and the selectively etching the oxygen-containing silicon film in this order is repeatedly performed.

4. The etching method of claim 3, wherein the desorbing the excess of the organic amine compound gas includes supplying a purge gas to purge an interior of a processing container in which the substrate is stored.

5. The etching method of claim 4, wherein the recess is formed by a silicon-containing material.

6. The etching method of claim 5, wherein the silicon-containing material is a silicon nitride.

7. The etching method of claim 6, wherein the organic amine compound gas is a gas of a compound having a linear alkyl group represented by CₙH₂ₙ₊₁, wherein n is an integer of 4 or more.

8. The etching method of claim 2, wherein the desorbing the excess of the organic amine compound gas includes supplying a purge gas to purge an interior of a processing container in which the substrate is stored.

9. The etching method of claim 1, wherein after the adsorbing the organic amine compound gas, the desorbing the excess of the organic amine compound gas and the selectively etching the oxygen-containing silicon film are performed in parallel, and the desorbing the excess of the organic amine compound gas includes supplying only the etching gas, among the organic amine compound gas and the etching gas, to the substrate.

10. The etching method of claim 1, wherein the adsorbing the organic amine compound gas and the selectively etching the oxygen-containing silicon film are performed in parallel.

11. The etching method of claim 1, wherein the recess is formed by a silicon-containing material.

12. The etching method of claim 1, wherein the organic amine compound gas is a gas of a compound having a linear alkyl group represented by CₙH₂ₙ₊₁, wherein n is an integer of 4 or more.

13. An etching method for etching an oxygen-containing silicon film by supplying an etching gas to a substrate, the etching method comprising:
adsorbing an organic amine compound gas on the oxygen-containing silicon film by supplying the organic amine compound gas to the substrate;
desorbing an excess of the organic amine compound gas from the substrate by supplying an inert gas to the substrate; and
etching the oxygen-containing silicon film by supplying the etching gas containing a halogen to the substrate on which the organic amine compound has been adsorbed.

14. The etching method of claim 13, wherein the organic amine compound gas is a gas of a compound having a linear alkyl group represented by CₙH₂ₙ₊₁, wherein n is an integer of 4 or more.

15. An etching apparatus for etching an oxygen-containing silicon film embedded in each recess of a substrate, which includes a plurality of recesses having different opening widths, by supplying an etching gas to the substrate, the etching apparatus comprising:
a processing container;
a stage provided in the processing container to place the substrate thereon;
an organic amine compound gas supplier configured to supply an organic amine compound gas into the processing container to be adsorbed on the oxygen-containing silicon film;
a desorption mechanism configured to desorb an excess of the organic amine compound gas from the substrate; and
an etching gas supplier configured to supply the etching gas containing a halogen into the processing container to selectively etch the oxygen-containing silicon film on which the organic amine compound has been adsorbed with respect to each recess.
